(19) United States
(12) Patent Application Publication
(10) Pub. No.: US 2017/0040262 A1
(43) Pub. Date: Feb. 9, 2017

(54) PACKAGE STRUCTURE OF A LIGHT-EMITTING DEVICE

(71) Applicant: NATIONAL CHIAO TUNG UNIVERSITY, Hsinchu City (TW)

(72) Inventors: Chien-Chung Lin, Taipei City (TW); Hao-Chung Kuo, Hsinchu County (TW); Chin-Wei Sher, Hsinchu County (TW); Hau-Vei Han, Hsinchu City (TW); Kuo-Ju Chen, Taichung City (TW); Zong-Yi Tu, Tainan City (TW); Hsien-Hao Tu, Hsinchu City (TW)

(21) Appl. No.: 15/000,048

(22) Filed: Jan. 19, 2016

(30) Foreign Application Priority Data
Aug. 6, 2015 (TW) 104125658

(51) Int. Cl. H01L 23/535; H01L 21/768; H01L 23/532

(52) U.S. Cl. CPC H01L 23/535; H01L 23/53271; H01L 21/76895

(57) ABSTRACT

A light-emitting device packaging structure is provided. The light-emitting device packaging structure includes a substrate, an array of light-emitting devices, an encapsulating layer, scattering particles, and a fluorescent material layer. The array of light-emitting devices is on the substrate. The encapsulating layer covers the array of light-emitting devices. The scattering particles are dispersed in the encapsulating layer. The fluorescent material layer is on the encapsulating layer.

### RELATED APPLICATIONS

This application claims priority to Taiwanese Application Serial Number 104125658, filed on Aug. 6, 2015, which is herein incorporated by reference.

### BACKGROUND

Technical Field

The present disclosure is related to a package structure, in particular to a package structure of a light-emitting device.

Description of Related Art

A light-emitting diode (LED) with the benefits of tiny volume, low energy consumption, long service life (over 100,000 hours) and environmental friendliness (shock-proof, impact resistance, breakage-proof, waste recycling, no pollution), is the green energy source of a new generation. In recent years, white light-emitting diodes are gradually applied in the car dashboards and the front light and back light of LCD. White light-emitting diodes emit white light mainly through hybridizing light emitted by the light-emitting diode and phosphor light. However, the conventional phosphor-converted white light-emitting diode package structure suffers from the problems of uneven distributions of color and brightness, which has restricted its practical applications.

Accordingly, what is needed is to develop a package structure of a light-emitting device, which can solve the above problems, to enhance the luminous efficiency of the package structure of a light-emitting device, thereby achieving versatility in application.

### SUMMARY

The present disclosure provides a package structure of a light-emitting device, which includes a substrate, a light-emitting device array, an encapsulating layer, scattering particles, and a fluorescent material layer. The light-emitting device array is disposed on the substrate. The encapsulating layer covers the light-emitting device array. The scattering particles are dispersed in the encapsulating layer. The fluorescent material layer is disposed on the encapsulating layer.

In an embodiment of the present disclosure, light-emitting device array includes a plurality of light-emitting diodes.

In an embodiment of the present disclosure, the encapsulating layer has a thickness of about 0.1-10 mm.

In an embodiment of the present disclosure, the plurality of scattering particles are present in an amount of about 0.1-10 by weight based on a total weight of the encapsulating layer.

In an embodiment of the present disclosure the plurality of scattering particles have a refraction index of about 10-5.0.

In an embodiment of the present disclosure, the plurality of scattering particles include zirconium oxide, titanium oxide, aluminum oxide, silicon oxide or a combination thereof.

In an embodiment of the present disclosure, the plurality of scattering particles have a particle size of about 20-500 μm.

In an embodiment of the present disclosure, the fluorescent material layer includes a silicone and a fluorescent powder dispersed in the silicone.

In an embodiment of the present disclosure, the package structure of a light-emitting device further includes a roughening layer disposed on the fluorescent material layer.

In an embodiment of the present disclosure, the roughening layer includes a plurality of pyramidal structures.

The package structure of a light-emitting device of the present disclosure utilizes a light-emitting device array and an encapsulating layer doped with scattering particles. A point light sources of a light-emitting unit is converted into a uniform surface light source by the scattering particles, thereby enhancing the luminous efficiency and uniformity of the package structure of a light-emitting device.

### BRIEF DESCRIPTION OF THE DRAWINGS

Other objects and aspects of the present invention will become apparent from the following descriptions of the embodiments with reference to the accompanying drawings in which:

FIG. 1 shows a cross-sectional view of the package structure of a light-emitting device according to an embodiment of the present disclosure;

FIG. 2 shows a cross-sectional view of the package structure of a light-emitting device according to another embodiment of the present disclosure;

FIG. 3 shows a plot of scattering particle concentration versus luminous efficiency of the package structure of a light-emitting device according to an example of the present disclosure;

FIG. 4 shows an emission spectrum of the package structure of a light-emitting device according to an example of the present disclosure and a comparative example;

FIG. 5 shows a color temperature distribution plot of the package structures of light-emitting devices according to examples of the present disclosure;

FIGS. 6A to 6C show images of luminous efficiency test of the package structures of light-emitting devices according to examples of the present disclosure; and

FIG. 7 shows a plot of thermal capacitance versus thermal resistance of the package structures of light-emitting devices according to examples of the present disclosure.

### DETAILED DESCRIPTION

In order to make a more detailed description of the invention and perfect for the embodiment of the present invention is presented below with particular illustrative embodiments described; but this is not the only form of practice or the use of specific embodiments of the present invention. The following are disclosed various embodiments may be combined or substituted with each other in a beneficial situation, but also in an embodiment, additional other embodiments without further described or explained In the following description numerous specific details are described in detail in order to enable the reader to fully understand the following examples. However, embodiments of the present invention may be practiced in case no such specific details. In other cases, in order to simplify the drawings, well-known structures and devices depicted only schematically in figures.

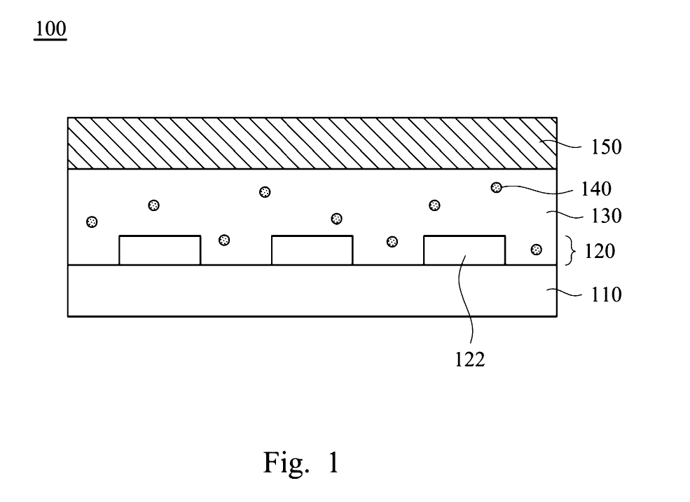

FIG. 1 shows a cross-sectional view of the package structure 100 of a light-emitting device according to an embodiment of the present disclosure.

The package structure 100 of a light-emitting device includes a substrate 110, a light-emitting device array 120, an encapsulating layer 130, scattering particles 140, and a fluorescent material layer 150. The light-emitting device array 120 is disposed on the substrate 110. The encapsulating layer 130 covers the light-emitting device array 120. The scattering particles 130 are dispersed in the encapsulating layer 130. The fluorescent material layer 150 is disposed on the encapsulating layer 130.

In an embodiment, the substrate 110 may be a flexible substrate, and may include polyimide (PI), polycarbonate (PC), polyethersulfone (PES), polyacrylate (PA), polynorbornene (PNB), polyethylene terephthalate (PET), polyetheretherketon (PEEK), polyethylene naphthalate (PEN), or polyetherimide (PEI). In an embodiment, the thickness of the substrate 110 is about 0.01-10 mm.

The light-emitting device array 120 includes a plurality of light-emitting units, and the light-emitting units may be arranged in an n1×n2 array, wherein n1 and n2 are independently selected from an integer greater than 1.

In an embodiment, the light-emitting units are light-emitting diodes 122. The light-emitting diode 122 may be a blue light-emitting diode chip (light-emitting wave band: 440 nm-475 nm), a red light-emitting diode chip (light-emitting wave band: 610 nm-660 nm), a green light-emitting diode chip (light-emitting wave band: 500 nm-535 nm), an amber light-emitting diode chip (light-emitting wave band 580 nm-600 nm) or an ultraviolet light-emitting diode chip (light-emitting wave band: 280 nm-400 nm), and the type of light-emitting diode 122 may be selected depending on actual requirements.

In another embodiment, the package structure 100 of a light-emitting device may be applied to other optical devices such as an organic light-emitting diode (OLED), a thin film solar cell or an organic solar cell etc., but the present disclosure is not limited thereto.

The thickness of the encapsulating layer 130 is associated with the light output effect of the package structure 100 of a light-emitting device. Specifically, the thicker the thickness of the encapsulating layer 130, the more uniform the light emitted from package structure 100 of alight-emitting device. According to an embodiment, the thickness of the encapsulating layer 130 is about 0.1-10 mm, and for example, it may be 0.1, 0.5, 1, 1.5, 2, 2.5, 3, 3.5, 4, 4,5, 5, 5.5, 6, 6,5, 7, 75,8, 8,5, 9, 9.5 or 10 mm.

The encapsulating layer 130 may be made of a transparent polymer or a translucent polymer, for example, a soft gel, an elastomer, a resin, or combinations thereof. In an embodiment, the resin is an epoxy resin, a silicone or an epoxy-silicone hybrid resin. Preferably, the encapsulating layer 130 used in the present disclosure is silicone.

The encapsulating layer 130 in the package structure 100 of a light-emitting device is doped with a plurality of scattering particles 140 to provide scattering properties. In the package structure 100 of a hg ht-emitting device, the point light sources of the light-emitting unit are converted into a uniform surface light source through the scattering particles 140. Therefore, the light utilization and uniformity of the light-emitting device array 120 may be increased effectively by the scattering particles 140, thereby improving the luminous efficiency of the package structure 100 of a light-emitting device. In addition, the scattering particles 140 may also effectively improve the color temperature distribution at different viewing angles, thereby improving the luminous quality of the package structure 100 of a light-emitting device, In an embodiment, the scattering particles 140 are doped in the encapsulating layer 130 by dispensing.

The concentration o the scattering particles 140 in the encapsulating layer 130 may affect the luminous efficiency of the package structure 100 of a light-emitting device 100. The higher the concentration of scattering particles 140, the better the uniformity of the package structure 100 of a light-emitting device. However, when the concentration of scattering particles 140 is too high, it will affect the light-emitting path, thereby affecting the luminous efficiency of the package structure 100 of a light-emitting device In an embodiment of the present disclosure the scattering particles 140 are present n an amount of about 0.1-10% by weight based on a total weight of the encapsulating layer 130, for example, 0.1 0.5, 1, 1.5, 2, 2.5, 3, 3.5 4, 4.5, 5, 5.5, 6, 6.5, 7, 7.5, 8, 8.5, 9, 9.5 or 10%. Preferably, the scattering particles 140 are present in an amount of about 0.1-5% by weight based on a total weight of the encapsulating layer 130. The aforementioned concentration range of the scattering particles 140 is the best formulation ratio, not only considering uniformity, but also taking into account improvement on the luminous efficiency. As such, the package structure 100 of a light-emitting device is a uniform surface light source with high efficiency.

It is noteworthy that t he distribution of scattering particles 140 in the encapsulating layer 130 may be uniform or non-uniform depending on actual requirements, to provide various scattering effects. For example, the non-uniform distribution may be a gradient distribution, partition distribution or random distribution. Gradient distribution may, for example, be the situation that the scattering particles 140 have a gradient distribution along its thickness, length or width direction in the encapsulating layer 130.

The refractive index of the scattering particles 140 may affect the scattering effects 140 of the light emitted by the light-emitting device array 120. Refractive index should be designed taking into account the overall device design, and a good design can reduce the total reflection to obtain a better luminous efficiency. In an embodiment, the refractive index of the scattering particles s about 1.0 to 5.0, for example 1.0, 15, 2.0, 2.5, 3.0, 3.5, 4.0, 4.5,

In an embodiment, the material for the scattering particles 140 may be zirconium oxide (ZrO₂), titanium oxide (TiO₂), alumina (AlO₂), silicon dioxide (SiO₂), or combinations thereof. When the material of scattering particles 140 is zirconia, its refractive index is about 2.6. When the material of the scattering particles 140 is titanium dioxide, the refractive index is about 2.2 to 2.6.

The particle size of the scattering particles 140 will also influence the scattering effect of light emitted by the light-emitting device array 120. The smaller the particle size, the better the scattering effect. In an embodiment, the particle size of the scattering particles 140 are about 20 to 500 μm for example, 20, 30 40, 50, 60 7 0, 80, 90, 100, 150, 200, 250, 300, 350, 400, 450 or 500 μm. It is noteworthy that t he particle size herein refers to the average particle diameter of the plurality of scattering particles.

The fluorescent material layer 150 includes silicone (not shown) and the fluorescent powder (not shown) dispersed in the silicone. In an embodiment, the thickness of the fluorescent material layer 150 is about 0.01-10 mm, for example, 0.01, 0.05, 0.1, 0.5 or 1 mm.

In the fluorescent material layer 150, different types of fluorescent powders may emit lights of different colors after excitation. In an embodiment, the fluorescent powder is yellow fluorescent powder, red fluorescent powder, blue fluorescent powder, green fluorescent powder, or combinations thereof.

It is noteworthy that the package structure 100 of a light-emitting device may be regulated to emit light having the desired color with the fluorescent powder in the light-emitting diodes 122 and the fluorescent material layer 150. For example, the light-emitting diode 122 is a blue light-emitting diode chip or ultraviolet light-emitting diode chip, and fluorescent powder is yellow fluorescent powder. After the blue light or UV light is hybridized with the yellow light generated by exciting the fluorescent powder, the package structure 100 of a light-emitting device emits white light. In an embodiment, the blue light-emitting diode chip is a gallium nitride (GaN)-based blue light-emitting diode chip, and the yellow fluorescent powder is yttrium aluminum garnet (Y3Al5O12:Ce, YAG) fluorescent powder.

The package structure of a light-emitting device according to the present disclosure scatters light emitted from the light-emitting device array by the scattering particles, to increase the light output and uniformity. The scattered light and the light generated by exciting the fluorescent powder of the fluorescent material layer are hybridized to form t he final light emitted from the package structure of a light-emitting device. The package structure of a light-emitting device according to the present disclosure converts the point light sources of the light-emitting unit into a uniform surface light source through the scattering particles.

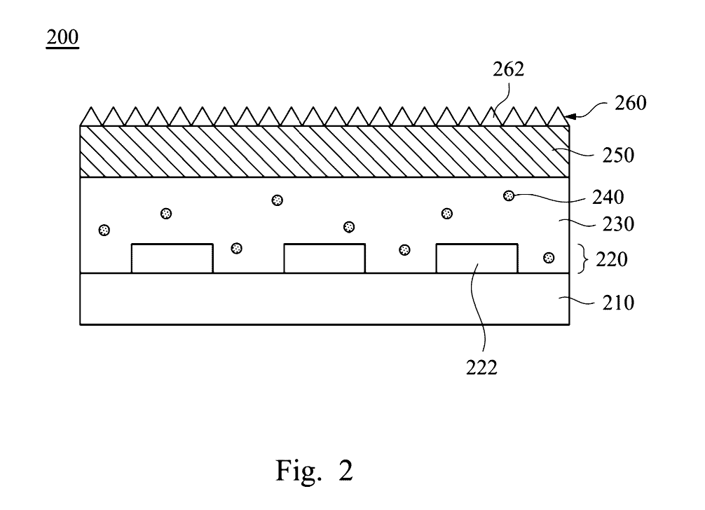

FIG. 2 shows a cross-sectional view of the package structure 200 of a light-emitting device according to another embodiment of the present disclosure. The package structure 200 of a light-emitting device includes a substrate 210, a light-emitting device array 220, an encapsulating layer 230, scattering particles 240, a fluorescent material layer 250 and a roughening layer 260. The light-emitting device array 220 is disposed on the substrate 210. The encapsulating layer 230 covers the light-emitting device array 220. The scattering particles 230 are dispersed in the encapsulating layer 230. The fluorescent material layer 250 is disposed on the encapsulating layer 230. The roughening layer 260 is disposed on the fluorescent material layer 250.

The package structure 200 of a light-emitting device further includes a roughening layer 260. The large difference in refractive indexes between the fluorescent material layer 250 and air is prone to result in a total reflection when light is transmitted from the fluorescent material layer 250 into air. In such a case, most of light may be limited within the interior of the package structure 200 of a light-emitting device and absorbed, thus significantly reducing the light extraction efficiency. The roughening layer 260 is provided to change the direction of the light which meets the condition of total internal reflection, destruct and reduce t he chance of total internal reflection when light is transmitted from the fluorescent material layer 250 into air, thereby increasing the light output. As such, the luminous efficiency and light-emitting uniformity of the package structure of a light-emitting device 280 can be enhanced. The pattern of the roughening layer 260 may be selected to be regular or Irregular depending on actual requirements.

In an embodiment, the material he of roughening layer 260 is polydimethylsiloxane (PDMS).

In an embodiment as shown in FIG. 2, the roughening layer 260 includes a plurality of pyramidal structures 262, which may have a conical shape or a pyramid shape, such as triangular pyramid quadrangular pyramid, pentagonal pyramid hexagonal pyramid and so on.

The difference between the package structure 200 of a light-emitting device and the package structure 100 of a light-emitting device is that the package structure 200 further includes a roughening layer 260, and this difference does not affect the characteristics of each element. Therefore, the package structure 200 has the same functions and the advantages as the package structure 100.

The package structure of a light-emitting device according to the present disclosure is characterized in that a light-emitting device array is employed, and an encapsulating layer is doped with the scattering particles, through which the point light sources of the light-emitting unit is converted into a uniform surface light source. The package structure of a light-emitting device according to the present disclosure may also include the roughening layer to damage and reduce the chance of total internal reflection, thereby enhancing the luminous efficiency and light-emitting uniformity of the package structure of a light-emitting device. The package structure of a light-emitting device according to the present disclosure has quite broad applications, and it can be applied in an optical device, such as an LED, an OLED, a thin film solar cell an organic solar cell and the like, having wide applications and big market.

### Method for Manufacturing the Package Structure of a Light-Emitting Device

The method for manufacturing the package structure of a light-emitting device according to embodiments of the present disclosure includes the following steps:

1. A light-emitting device array including a plurality of light-emitting units is formed on a substrate by flip-chip technique. In an embodiment, the substrate is a flexible substrate, made of polyimide (PI), and the light-emitting unit is a blue light-emitting diode chip.

2. An encapsulating layer is formed to cover the light-emitting device array. In an example, the material of the encapsulating layer is silicone.

3. Scattering particles are doped in the encapsulating layer by adhesive dripping. In an example, the scattering particles are zirconia (ZrO₂).

4. The silicone is mixed with fluorescent powder, to prepare a fluorescent material layer by spin coating. In an example, the fluorescent powder is yellow fluorescent powder.

5. The fluorescent material layer obtained in Step 4 is bonded to the structure obtained in Step 3.

6. A roughening layer is formed on the fluorescent material layer of the structure obtained in step 5, to obtain the package structure of a light-emitting device according to the present disclosure, as shown in FIG. 2. In an example, the roughening layer is made of polydimethylsiloxane (PDMS), and composed of a plurality of pyramidal structures.

The package structure of a tight-emitting device manufactured by the above-described method is subjected to the following tests.

### Luminous Efficiency Test

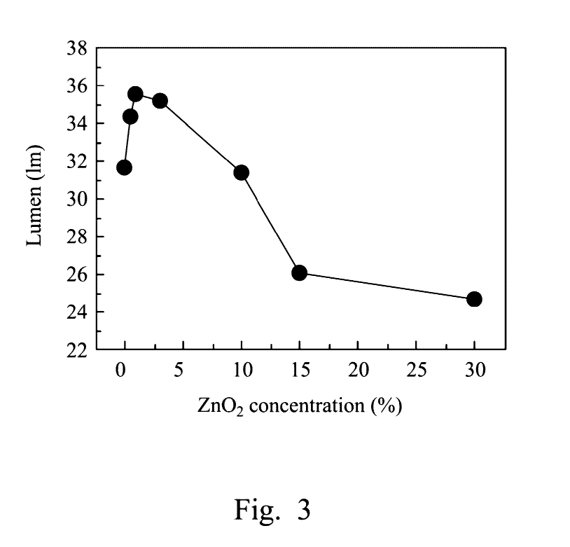

First, tests for the influence of the scattering particle concentration on the luminous efficiency of the package structure of a light-emitting device are performed. Refer to FIG. 3, which illustrates a plot of scattering particle concentration versus luminous efficiency of the package structure of a light-emitting device according to an example of the present disclosure. The tests is performed by measuring the luminous efficiency in Lumen (lm) of the package structure of a light-emitting device doped with different concentrations of the scattering particles, wherein the scattering particles is zirconia (ZrO₂), and the concentration un t is weight percentage. As shown in FIG. 3, when the encapsulating layer is not doped with zirconia nanoparticles, its luminous efficiency is between 31 lm to 32 lm. However, when the encapsulating layer is doped with the zirconia nanoparticles, their luminous efficiency will increase to be between 34 lm and 36 lm. Thus, the results shown in FIG. 3 of the present disclosure confirm that the encapsulating layer doped with the zirconia nanoparticles having scattering properties is certainly conducive to improving the luminous efficiency of the package structure of a light-emitting device. It is noteworthy that the zirconia nanoparticles are doped preferably in amount of between 0-5% by weight in the encapsulating layer, which may improve the luminous efficiency of up to about 12.5%. As shown in FIG. 3, when the doping amount of zirconia nanoparticles is too high, the luminous efficiency is decreased since too many nanoparticles will negatively affect the light-emitting path.

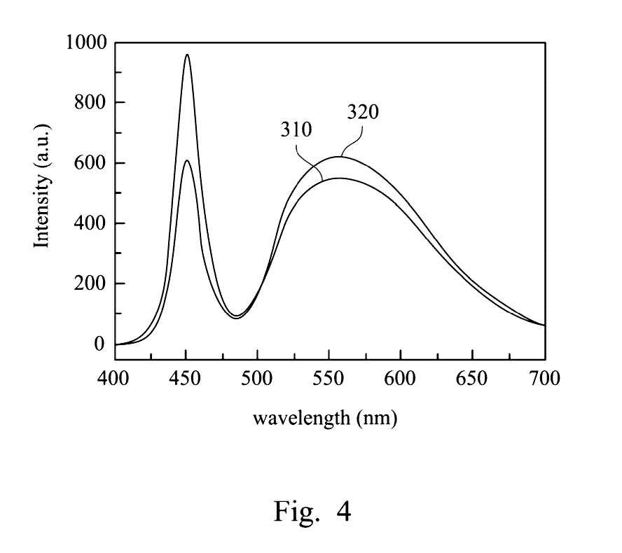

Next, the luminous efficiencies of the package structure of a light-emitting device according to the example of present disclosure and a conventional one are compared. Refer to FIG. 4, which illustrates an emission spectrum of the package structure of a light-emitting device according to an example of the present disclosure and a comparative example. Line 310 represents the emission spectrum of the comparative example, while lines 320 represents the emission spectrum of the example. The luminous intensity (unit: a.u.) in different wavelengths of the package structure of a light-emitting device light can be seen by the emission spectrum. In this test, the zirconia nanoparticles are present in an amount of about 1% by weight based on a total weight of the encapsulating layer in the package structure of a light-emitting device. As shown in FIG. 4, compared with the comparative example, in the emission spectrum of the light-emitting diode structure according to the example of the present disclosure, the intensity in the blue band of 450 nm to 495 nm is obviously decreased, while the intensity in the yellow band of 570 nm to 590 nm yellow zone is increased. The results shown in FIG. 4 sufficiently prove that the introduction of the zirconia nanoparticles into the encapsulating layer according to the invention is indeed conducive to enhancing utilization and uniformity of the blue light thereby improving the luminous efficiency of the light-emitting diode structure.

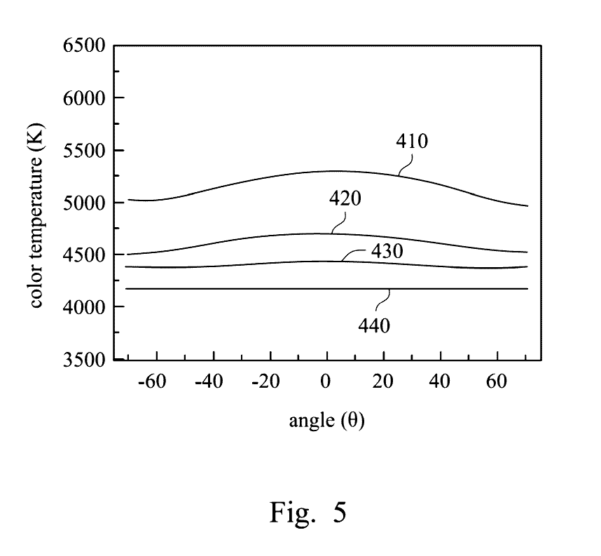

Next, tests for the influence of the concentration of the scattering particles on the color temperature of light emitted by the package structures of light-emitting devices are performed. Refer to FIG. 5, which illustrates a color temperature distribution plot of the package structures of light-emitting devices according to examples of the present disclosure. This test is performed on the package structures of light-emitting devices doped with different concentrations of the scattering particles, to measure their color temperature (unit: K) of the light emitted at different angles (θ), wherein the scattering particles is zirconia (ZrO₂) and the concentration unit is weight percentage. Lines 410, 420 430 and 440, respectively, indicate the color temperature distributions of the package structures of light-emitting devices having the encapsulating layers doped with 0.5%, 1%, 3% and 10% of the scattering particles at different viewing angles. As shown in FIG. 5, when the encapsulating layer is doped with only 0.5 wt % of zirconia nanoparticles, the color temperature at different angles is distributed between 5000K and 5500K. With gradually increase in doping amount of the zirconia nanoparticles from 1%, 3% up to 10%, and the color temperature distributions at different angles tend to be a straight line. That is, the encapsulating layer doped with the zirconia nanoparticles can improve the color temperature distributions at different angles, thereby improving the luminous quality. Since the zirconia nanoparticles possess scattering effect, they can contribute to the scattering of the blue light emitted from the light-emitting diode. Previous studies pointed out that the larger the blue light radiation pattern, the more uniform the color temperature of the overall white light at different angles. As such, the yellow circle phenomenon may be reduced, thereby achieving a white light source having a higher quality. Therefore, the improvement in the color temperature distribution can indeed improve the luminous quality.

Thus, the package structure of a light-emitting device provided by the present disclosure incorporates the scattering particles into the encapsulating layer, which riot only can improve the luminous efficiency, but also improve the color temperature distribution at different angles, thereby improving the luminous quality. The doping amount of the scattering particles in the encapsulating layer may be adjusted according to the above conditions to obtain an optimized effect.

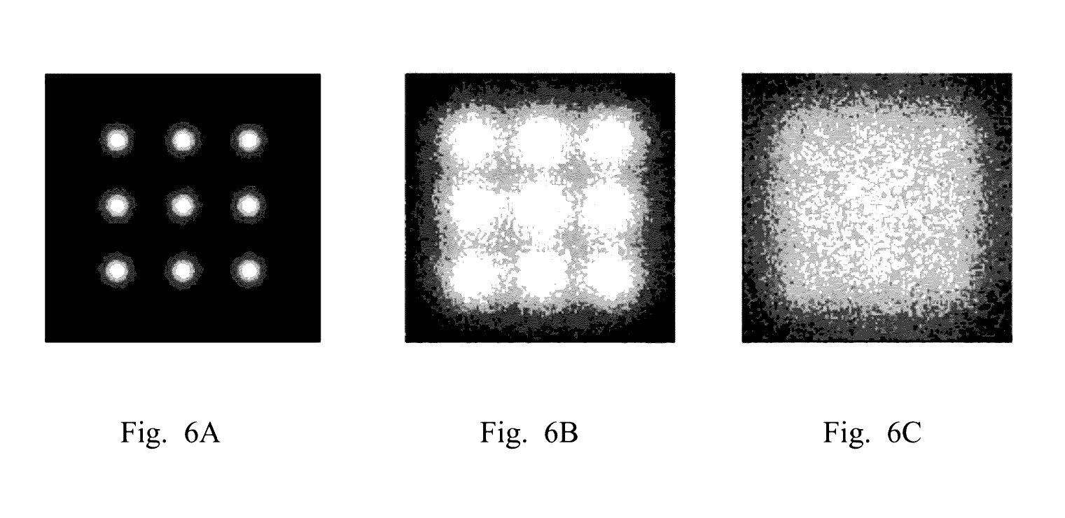

FIGS. 6A to 6C show images of luminous efficiency test of the package structures of light-emitting devices according to examples of the present disclosure. This test uses the package structures of a light-emitting device with different thicknesses for the encapsulating layer, and the light emitted therefrom are observed, wherein FIGS. 6A to 6C illustrate, respectively, the examples of the encapsulating layers having thickness of 1 mm, 5 mm and 10 mm. According to the results of the FIGS. 6A to 6C, it can be known that the thicker the thickness of the encapsulating layer, the better the effect of the conversion from the point light sources into a surface light source. The package structure of a light-emitting device of the present disclosure employs a light-emitting device array and the encapsulating layer doped with the scattering particles. The package structure of a light-emitting device manufactured by such a method can convert light point sources into a uniform and thin surface light source, thus resolving the most troublesome problem of a point light source, that is, the unformity of the light-emitting surface.

### Heat Resistance Test

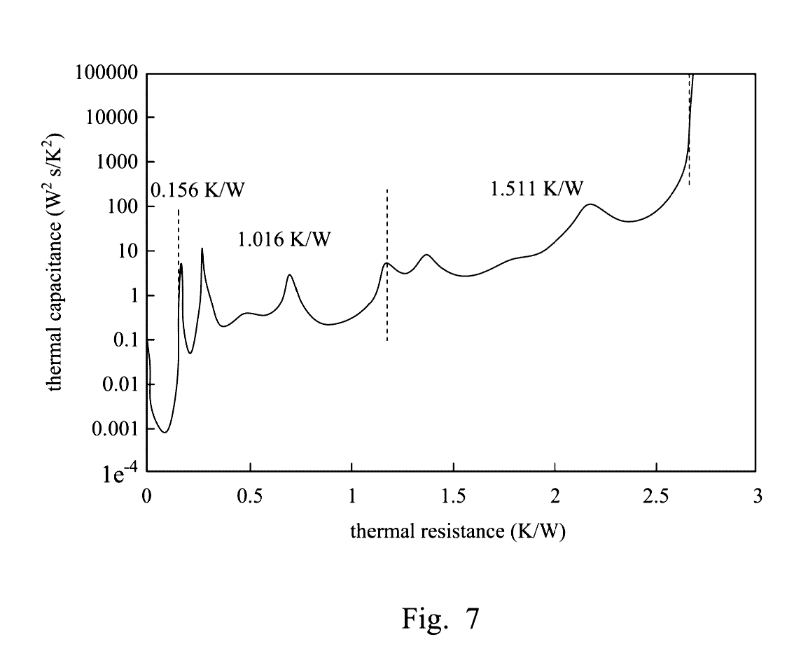

FIG. 7 shows a plot of thermal capacitance versus thermal resistance of the package structures of light-emitting devices according to examples of the present disclosure, in which the unit of the thermal capacitance is W²s/K², and the unit of the thermal resistance is K/W. In this test, in the package structure of a light-emitting device in the example, the zirconia nanoparticles are present in an amount of 5% by weight based on a total weight of the encapsulating layer, In FIG. 7 the intervals between the ordinate axis and the three tangents, from left to right, represent the thermal resistances of the light-emitting diode chip, anisotropic conductive film (ACF), and polyimide substrate, respectively. As shown in FIG. 7, the thermal resistance of the light-emitting diode chip is 0.156 K/W the thermal resistance between the chip and the substrate is 1.016 K/W and the thermal resistance of the polyimide substrate is 1.511 K/W. The package structure of a light-emitting device according to an example of the present disclosure has a total thermal resistance of 2,683 K/W, which is greatly reduced compared to that manufactured by a conventional eutectic process (having a thermal resistance of approximately 5-010 K/W). Thus, the package structure of a light-emitting device according to the present disclosure can reduce the thermal resistance, indicating that heat in the light-emitting device can be conducted to outside quickly, thus prolonging the service life of the light-emitting device.

In summary, the package structure of a light-emitting device of the present disclosure is a uniform and efficient package structure, and it utilizes the light-emitting device array and the scattering particles to convert the point light source of the light-emitting device into a uniform surface light source. In addition the package structure of a light-emitting device according to the present disclosure has a low thermal resistance, and the service life of the light-emitting device can be prolonged. The package structure of a light-emitting device according to the present disclosure may further include a roughening layer, which can damage and reduce the chance of light total internal reflection, thereby enhancing the luminous efficiency and uniformity of the package structure of a light-emitting device. Furthermore, when the substrate is a flexible substrate, the package structure of a light-emitting device according to the present disclosure is a flexible structure. Compared to the organic light-emitting diode (OLED), it has a have better performance in luminous efficiency and color uniformity. The package structure of a light-emitting device according to the present disclosure may be applied to a photoelectric or electronic technology industry, and applied to products such as a lamp, lighting, backlighting, wearable device, vehicle, motorcycle, transportation, mobile phone and so on.

While the invention has been shown and described with reference to certain exemplary embodiments thereof, it will be understood by those skilled in the art that various changes in form and details may be made therein without departing from the scope of the invention as defined by the appended claims.

1-20. (canceled)

21. A package structure of a light-emitting device, comprising:
substrate;
a light-emitting device array disposed on the substrate;
a single encapsulating layer covering the light-emitting device array, wherein the single encapsulating layer has a thickness of about 0.1-10 mm;
scattering particles dispersed in the single encapsulating layer; and
a fluorescent material layer disposed on the single encapsulating layer.

22. The package structure of the light-emitting device of claim 21, wherein the light-emitting device array comprises a plurality of light-emitting diodes.

23. (canceled)

24. The package structure of the light-emitting device of claim 21, wherein the scattering particles are present in an amount of about 0.1-10% by weight based on a total weight of the single encapsulating layer.

25. The package structure of the light-emitting device of claim 21, wherein the scattering particles have a refraction index of about 1.0-5.0.

26. The package structure of the light-emitting device of claim 21, wherein the scattering particles comprise zirconium oxide, titanium oxide, aluminum oxide, silicon oxide or a combination thereof.

27. The package structure of the light-emitting device of claim 21, wherein the scattering particles have a particle size of about 20-500 nm.

28. The package structure of the light-emitting device of claim 21, wherein the fluorescent material layer comprises a silicone and a fluorescent powder dispersed in the silicone.

29. The package structure of the light-emitting device of claim 21, further comprising a roughening layer disposed on the fluorescent material layer.

30. The package structure of the light-emitting device of claim 29, wherein the roughening layer comprises a plurality of pyramidal structures.
